(19) United States
(12) Patent Application Publication
(10) Pub. No.: US 2008/0158828 A1
(43) Pub. Date: Jul. 3, 2008

(54) Heatsink structure and assembly fixture thereof

(75) Inventor: Win-Haw Chen, Taipei (TW)

Correspondence Address: RABIN & Berdo, PC, 1101 14TH STREET, NW, SUITE 500, WASHINGTON, DC, 20005, US

(73) Assignee: INVENTEC CORPORATION, Taipei (TW)

(21) Appl. No.: 11/645,501

(22) Filed: Dec. 27, 2006

(51) Int. Cl. H05K 7/20

(52) U.S. Cl. 361/719

(57) ABSTRACT

A heatsink structure including a heat conductor is provided. The heat conductor has a first surface and a second surface. A plurality of heatsink fins is erected on the first surface, and the second surface is attached to a heat-generating element of a printed circuit board (PCB). A pair of fixing posts passing through the PCB is disposed on the second surface. An elastic element is sleeved on each of the fixing posts, and a buckling piece is disposed at one end of each of the fixing posts. The elastic element is pressed between the PCB and the buckling piece, such that the heat conductor tightly contacts the heat-generating element to conduct heats.

### BACKGROUND OF THE INVENTION

1. Field of Invention

The present invention relates to a heatsink structure, and more particularly, to an arrangement means for assembling or supporting a heatsink.

2. Related Art

As the rapid progress of information technology and the prevailing of the application of computers, heatsinks have been more widely applied in various precision electronic devices such as computers and notebook computers. Electronic components, e.g., CPU chips and power ICs, in such electronic devices will generate heats during the operation. As the working temperature is an important factor for causing the electronic devices to be crashed, if the temperature is properly controlled, the electronic devices will have higher reliability, and the heat-generating electronic components will maintain a stable operation.

In order to achieve the maximum heat dissipation effect of a heatsink, the heatsink has to be tightly attached to the heat-generating electronic component to fully conduct the heats outwards, and thus, the temperature of the electronic component can be more effectively reduced. Currently, there are two ways for fixing the heatsink, namely, a locking mode and a leaf spring mode. As for the locking mode, a heat conductor disposed at the bottom of the heatsink is attached on the heat-generating element, and screws or tenons are utilized to pass through holes or slots in the heat conductor, and thereby being directly locked or fixed within through holes in a PCB in a downward direction. Thus, the locking or fixing force of the screws or the tenons directly generates a downward force on the heatsink, so as to attach the heat conductor to the heat-generating element. Alternatively, a spring is sleeved on each of the screws or tenons, and the screws or tenons also pass through the holes or slots in the heat conductor, and thereby being directly locked or fixed in the through holes in the PCB. The resilient force generated by the springs compressed between the heatsink and the screws exerts a downward force to the heatsink for attaching the heatsink to the heat-generating element, such that the heatsink is tightly contacted with the heat-generating element, thereby conducting the heat. As for the leaf spring mode, a fixing seat or bracket is added around the heat-generating element on the PCB, an elastic arm or a buckling member is disposed on the fixing seat or the bracket, and a buckling portion for being buckled with the elastic arm or the buckling member is also disposed on the fixing seat or the bracket. First, the heat conductor of the heatsink is attached on the heat-generating element, and then, the elastic arm or the buckling member is pressed on the heatsink and buckled with the buckling portion. The fixing function of the elastic arm or fixing member is used to exert a downward press to the heatsink, such that the heat conductor of the heatsink is attached to the heat-generating element tightly, so as to conduct the heats to the heatsink, and thereby achieving the heat dissipation.

Both the locking mode and the leaf spring mode utilize screws, tenons, elastic arm, or buckling member to exert a pressing force to the heatsink, such that the heatsink is attached to the electronic component for dissipating heats. However, in both of the above two modes, a press is required to be applied on the heatsink for fixing the heatsink, and the heatsink must have through holes for the screws or tenons to pass through, or have positions for the members that exert the force e.g., the elastic arm or the buckling member to be buckled with each other. Due to the arrangement of the through holes or the buckling positions, the area for disposing heatsink fins on the heatsink substrate is substantially reduced, which restricts the heat dissipation area, and further influences the heat dissipation efficiency.

In order to solve the problem of arranging heatsink fins of the heatsink, Taiwan Patent Publication No. M293475 (hereafter called “475”) discloses a heatsink, wherein a plurality of fixing posts is arranged underneath the heatsink, a plurality of through holes corresponding to the fixing posts is arranged in a PCB, and fixing members are arranged at positions of a case corresponding to the fixing posts of the heatsink. The fixing posts and the fixing members have internal screw holes and external threads respectively, and washers and springs are sleeved on the fixing members. Then, the fixing members are locked on the fixing posts. In Case 475, the buckling positions are not required to be reserved, so as to increase the space for the heatsink fins, and thereby increasing the heat dissipation area. However, in the actual manufacturing process, automatic or semiautomatic assembly fixtures are generally used for assembling. But the automatic or semiautomatic assembly fixtures-cannot be applied to the part requiring screwing operations, so that workers on the production line have to screw the fixing members to the fixing posts one by one. Therefore, the more the fixing posts are, the more screwing operations will be required. Furthermore, it must pay more attention to the point whether the springs are properly sleeved on the fixing members during the locking process. Therefore, the manufacturing and assembling process will become more complicated if the screwing process is adopted, and the overall manufacturing cost will be increased.

### SUMMARY OF THE INVENTION

The conventional method for fixing heatsinks includes a direct locking mode and a leaf spring buckling mode, which occupy the space for arranging the heat fins, so the overall heat dissipation area is reduced. In addition, the design that uses fixing posts of the heatsink to be directly screwed with the fixing members is provided to solve the aforementioned problem. However, the above design is inconvenient for manufacturing. Therefore, the conventional methods for fixing heatsinks are not optimal designs. Accordingly, the present invention provides a heatsink structure that can be fixed through an assembly fixture and the assembly fixture design thereof.

The heatsink structure according to the present invention comprises a heat conductor, an elastic element, and a buckling piece. The heat conductor has a first surface and a second surface, wherein a plurality of heatsink fins is disposed on the first surface; the second surface contacts a heat-generating element, and a pair of fixing posts is disposed on the second surface. A heat-generating element is disposed on a PCB, through holes are arranged near the heat-generating element in the PCB, the two fixing posts pass through the through holes in the PCB, a fixing slot is arranged at one end of each of the fixing posts for the elastic element to be sleeved on the fixing posts, and the elastic element is pressed between the PCB and the buckling piece, and thus, the second surface of the heat conductor tightly contacts the heat-generating element for transferring heats.

The heatsink structure can rapidly attach the heatsink to the heat-generating element tightly using a simple combination of the fixing posts, the elastic element, and the buckling piece, so as to transfer the heat. Moreover, in order to assemble the heatsink structure more conveniently and rapidly, the present invention further provides an assembly fixture, which comprises a fixing member, wherein the fixing member has an accommodation slot, and a spring and a movable member are disposed within the accommodation slot. The spring is pressed against the movable member, such that the movable member has at least a first position extending out of the accommodation slot and a second position being retracted within the accommodation slot. When the movable member is located at the first position, the buckling piece and the elastic element are allowed to be sleeved sequentially, the movable member is corresponding to the fixing post, and then, when the fixing post is pushed, the movable member moves from the first position towards the second position, such that the elastic element is sleeved on the fixing post, and the buckling piece is buckled with the buckling slot.

According to the heatsink structure and the assembly fixture disclosed in the present invention, a pair of fixing posts passing through the PCB is arranged on the bottom of the heatsink. Thus, the number of the heatsink fins that can be arranged is increased, and the heatsink can be rapidly fixed on the heat-generating element of the PCB through using the assembly fixture. Therefore, the time cost and the number of operators required in the assembling operation are greatly reduced, and thus, the cost for assembling the heatsink is also reduced effectively.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, which thus is not limitative of the present invention, and wherein:

FIG. 1A is a stereogram of a heatsink structure;

FIG. 1B is a sectional view of the heatsink structure;

FIG. 2 is an exploded view of the heatsink structure;

FIG. 3A is a stereogram of an assembly fixture for the heatsink structure;

FIG. 3B is a sectional view of the assembly fixture for the heatsink structure;

FIG. 4A is a schematic view of a first position of the assembly fixture for the heatsink structure;

FIG. 4B is a schematic view of a second position of the assembly fixture for the heatsink structure; and

FIGS. 5A, 5B, and 5C are schematic views of assembling motions for the heatsink structure.

### DETAILED DESCRIPTION OF THE INVENTION

According to the heatsink structure and the assembly fixture disclosed in the present invention, the heatsink is disposed on a heat-generating element on a PCB to dissipate the heats generated by the heat-generating element. The PCB refers to a mainboard of a computer system or a server system, the heat-generating element refers to a CPU of the computer system or the server system. However, the heat-generating element that requires heat dissipation is not limited to the CPU of the computer system or the server system. In the detailed embodiments below, the preferred embodiments of the present invention are illustrated by taking the CPU of the computer system as an example for the heat-generating element that requires heat dissipation.

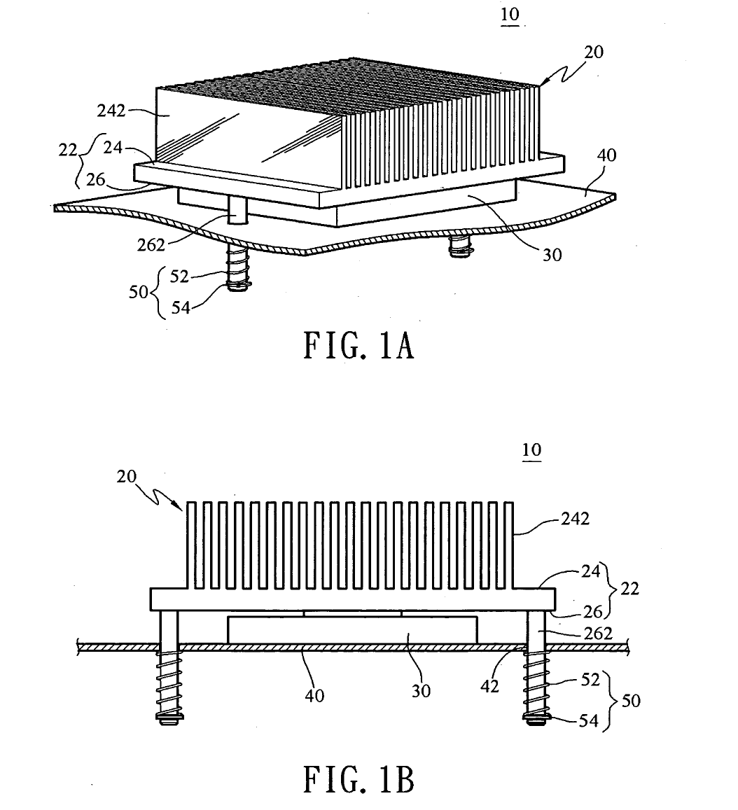

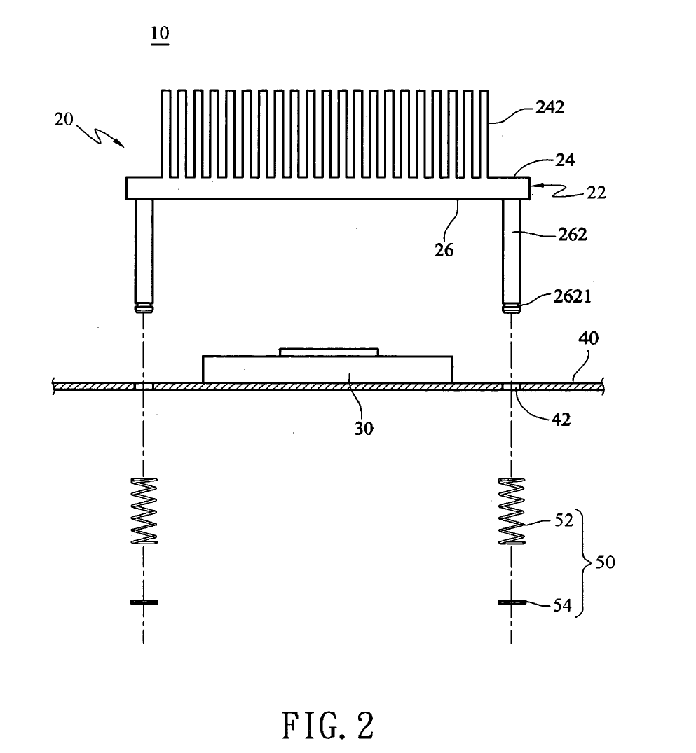

Referring to FIG. 2, a heatsink structure 10 in the present invention (shown in FIGS. 1A and 1B) includes a heatsink 20, a CPU 30, a printed circuit board (PCB) 40, and assembling components 50.

The heatsink 20 includes a heat conductor 22. The heat conductor 22 has a first surface 24 and a second surface 26 opposite to the first surface 24. A plurality of heatsink fins 242 is erected on the first surface 24, such that the first surface 24 rapidly conducts the absorbed heats to the open air. The second surface 26 is attached to the CPU 30 that generates heats during operation. The CPU 30 is disposed on the PCB 40, and the PCB 40 has a pair of through holes 42 near the periphery of the CPU 30. A pair of fixing posts 262 is disposed on the second surface 26 of the heat conductor 22, and the distance between the two fixing posts 262 is equal to that between the two through holes 42 in the PCB 40. The inner diameter of the through holes 42 is slightly larger than the outer diameter of the fixing posts 262, so the fixing posts 262 can pass through the through holes 42 and suspend on the PCB 40 after being aligned with the through holes 42, and the fixing posts 262 are attached to the CPU 30 on the PCB 40. In addition, a buckling slot 2621 is arranged at one end of each of the fixing posts 262.

Each of the assembling components 50 includes a first spring 52 and a C-shaped buckle 54. The first spring 52 is sleeved on one of the fixing posts 262, and the C-shaped buckle 54 is flexible, which thus can be sleeved in the buckling slot 2621. As the length of the first spring 52 in the normal state is larger than the distance between the PCB 40 and the C-shaped buckle 54 in the heatsink structure 10, the first spring 52 is compressed by the PCB 40 and the C-shaped buckle 54, so as to generate a resilient force for resisting the compression, and thus, the first spring 52 is compressed between the PCB 40 and the C-shaped buckle 54. As the first spring 52 exerts an upward resilient force on the PCB 40, the PCB 40 is pushed upwards by the force, and drives the CPU 30 to get closer to the second surface 26 of the heat conductor 22, and thus, the heat conductor 22 tightly contacts the CPU 30, and thereby conducting heats.

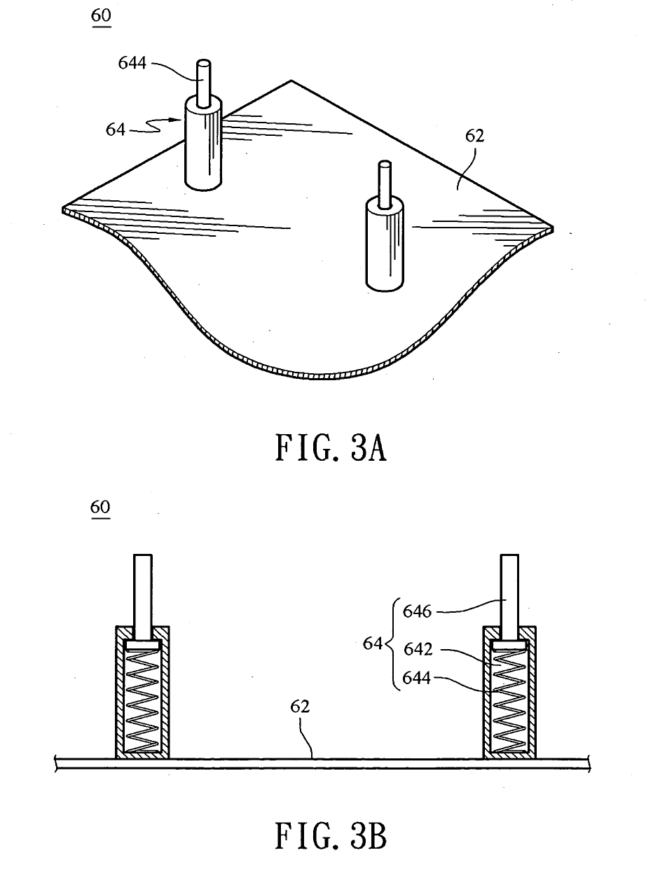

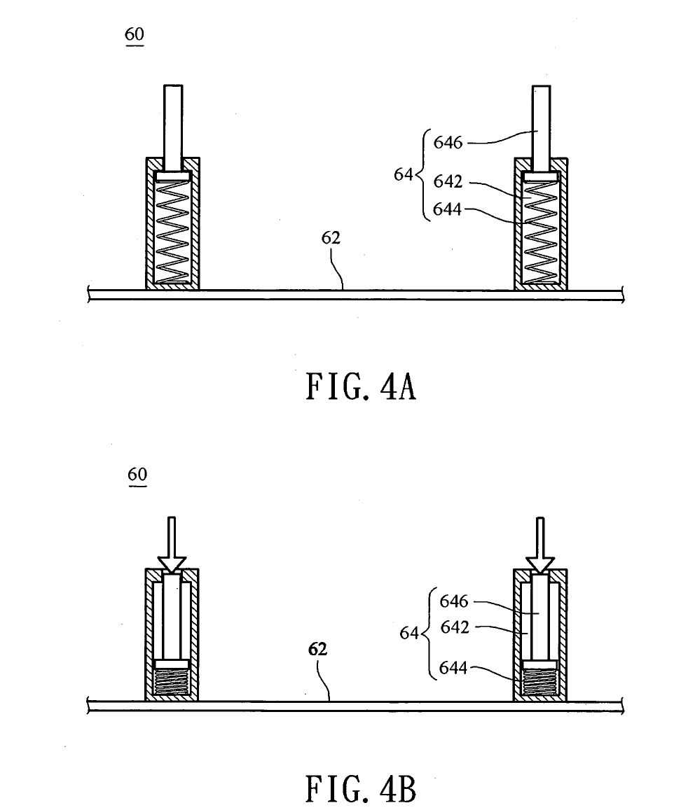

Referring to FIGS. 3A and 3B, the present invention provides an assembly fixture 60 for the heatsink structure 10. The assembly fixture 60 includes a platform 62. A pair of fixing members 64 is disposed on the platform 62, and each of the fixing members 64 has an accommodation slot 642. A second spring 644 and a movable member 646 are disposed in the accommodation slot 642. The second spring 644 is pressed against the movable member 646, and thus, the movable member 646 maintains the state of extending out of the accommodation slot 642 when no external force is applied, and when an external force is applied on the movable member 646, the second spring 644 is compressed as the movable member 646 is forced to move downwards. In addition, as the inner diameter of the accommodation slot 642 is slightly larger than the outer diameter of the movable member 646, and the length of the movable member 646 is smaller than the height of the accommodation slot 642, when being exerted by an external force, the movable member 646 moves between a first position extending out of the accommodation slot 642 and a second position being retracted within the accommodation slot 642 (see FIGS. 4A and 4B). When the movable member 646 is located at the first position, the C-shaped buckle 54 and the first spring 52 are allowed to be sleeved sequentially; when the movable member 646 is located at the second position, due to the downward movement of the movable member 646, the first spring 52 and the C-shaped buckle 54 are released from the movable member 646 and buckled with the accommodation slot 642. Moreover, the platform 62 further includes a lifting support 66 to support the PCB 40. The PCB 40 is placed on the lifting support 66, and the through hole 42 of the PCB 40 is aligned with the movable member 646. By rapidly exerting a force, the lifting support 66 is forced to move towards the platform 62, such that the PCB 40 contacts the assembling component 50.

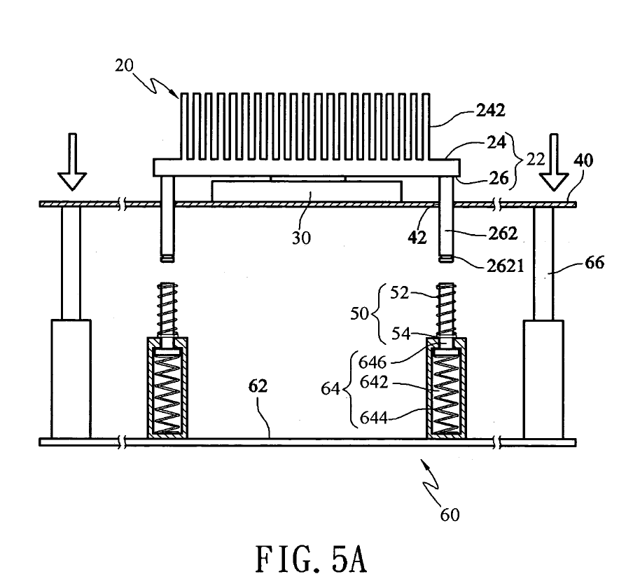

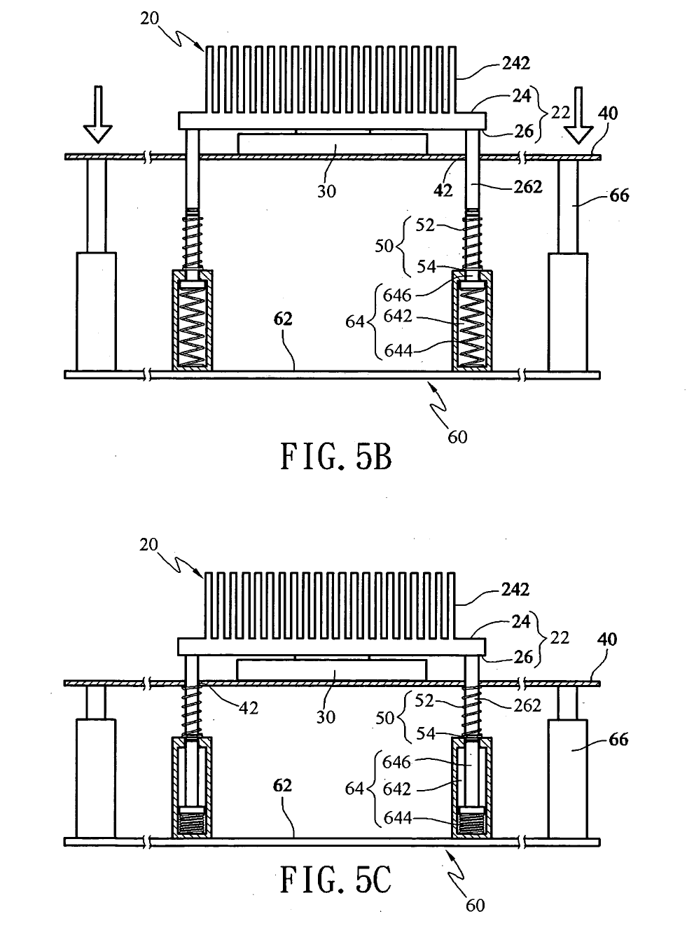

Referring to FIGS. 5A, 5B, and 5C, the heat conductor 22 of the heatsink 20 is attached to the CPU 30, such that the fixing posts 262 on the second surface 26 pass through the through holes 42 of the PCB 40. The heatsink 20 and the PCB 40 are placed on the lifting support 66, and the fixing posts 262 passing through the through holes 42 are aligned with the movable member 646 properly, and thus, the fixing posts 262 are corresponding to the movable member 646 at the above. A force is exerted to move the lifting support 66 towards the platform 62, such that the fixing posts 262 press the movable member 646 downwards, and accordingly, the movable member 646 moves downwards to compress the second spring 644. Thus, the movable member 646 moves from the first position to the second position, and is retracted into the accommodation slot 642. The outer diameter of the movable member 646 is smaller than the inner diameter of the first spring 52 and the C-shaped buckle 54, and as the movable member 646 is retracted into the accommodation slot 642, the first spring 52 and the C-shaped buckle 54 are released from the movable member 646, and thereby being sleeved on a fixing post 262. At this time, the first spring 52 is sleeved on the fixing post 262, and the C-shaped buckle 54 is sleeved in the buckling slot 2621. As the inner diameter of the C-shaped buckle 54 is slightly smaller than the outer diameter of the buckling slot 2621, the C-shaped buckle 54 can be buckled with the fixing post 262 tightly and fix the position of the first spring 52. Thus, the first spring 52 will not fall down to get separated from the fixing post 262, but it is compressed between the PCB 40 and the C-shaped buckle 54 due to being pressed by the C-shaped buckle 54. Therefore, the heat conductor 22 tightly contacts the CPU 30 to transfer heats.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A heatsink structure, applicable for being attached to a heat-generating element disposed on a printed circuit board (PCB) with at least a pair of through holes, comprising:
a heat conductor, having a first surface and a second surface opposite to the first surface, wherein the second surface is attached to the heat-generating element;
a plurality of heatsink fins, erecting on the first surface;
at least a pair of fixing posts, disposed on the second surface, and passing through the pair of through holes in the PCB, wherein a buckling slot is arranged near one end of each of the fixing posts;
at least a pair of elastic elements, disposed on the pair of fixing posts; and
at least a pair of buckling pieces, buckled with the buckling slots, such that the pair of elastic elements are compressed between the PCB and the buckling pieces.

2. The heatsink structure as claimed in claim 1, wherein a length of the elastic element is larger than a distance between the PCB and the buckling piece.

3. The heatsink structure as claimed in claim 1, wherein the heatsink is assembled through an assembly fixture, the assembly fixture comprising:
a fixing member, having an accommodation slot, wherein a spring is disposed in the accommodation slot; and
a movable member, movably disposed in the accommodation slot for bearing against the spring, wherein the movable member has at least a first position extending out of the accommodation slot and a second position retracted within the accommodation slot;
wherein when the movable member is located at the first position, the buckling pieces and the elastic members are allowed to be sleeved sequentially, the movable member is corresponding to the fixing posts, and the fixing member is pushed to sleeve the elastic elements on the fixing posts, and to buckle the buckling pieces with the buckling slots.

4. The heatsink structure as claimed in claim 3, further comprising a platform, wherein equal number of fixing members and fixing posts are disposed on the platform.

5. The heatsink structure as claimed in claim 4, wherein the platform has a lifting support for supporting the PCB.

6. The heatsink structure as claimed in claim 5, wherein the lifting support fixes the PCB at a position parallel to the platform.

7. The heatsink structure as claimed in claim 5, wherein the lifting support makes the through holes of the PCB and the movable member to correspond to each other.
